(19) United States
(12) Patent Application Publication
(10) Pub. No.: US 2001/0021476 A1
(43) Pub. Date: Sep. 13, 2001

(54) Phase mask

(76) Inventors: Fritz Gans, Munchen (DE); Uwe Griesinger, Munchen (DE); Rainer Pforr, Dresden (DE)

Correspondence Address: LERNER AND GREENBEG, P.A., Post Office Box 2480, Hollywood, FL, 33022-2480, US

(21) Appl. No.: 09/761,810

(22) Filed: Jan. 16, 2001

(30) Foreign Application Priority Data
Jan. 13, 2000 (DE) 100 01 119.5

(51) Int. Cl. G03B 27/42; G03F 9/00; G21K 5/10; H01J 37/08

(52) U.S. Cl. 430/5; 355/53; 250/492.22

(57) ABSTRACT

The phase mask is provided for illuminating a photo-sensitive layer in a photolithography process for producing integrated circuits with a predetermined pattern of optically transmissive regions. The phase mask is configured, in zones in which the distances between neighboring regions in at least one geometrical direction are less than a predetermined limiting distance, in each case as an alternating phase mask. The zones with isolated contact windows are in each case configured as a halftone phase mask or a chromeless phase mask.

### BACKGROUND OF THE INVENTION

Field of the Invention

The invention lies in the integrated technology field. More specifically, the invention pertains to a phase mask for illuminating a photosensitive layer in a photolithography process for producing integrated circuits with a predetermined pattern of optically transmissive regions.

Such phase masks are used in photolithography processes for producing integrated circuits, in particular for producing junctions of interconnects for wiring integrated circuits.

These integrated circuits are incorporated in a semiconductor substrate, which is usually formed by a silicon wafer. The interconnects are incorporated in insulator layers which are located directly, or with the interposition of a metal layer, on the semiconductor substrate. In order to produce junctions of interconnects in the insulator layer, vias and trenches extending in a single plane or in several planes are incorporated, etching processes being preferably used for this, in particular plasma etching processes. In order to incorporate these trenches and vias in the insulator layer, a resist mask having a pattern of holes corresponding to the trenches and/or the vias is applied to the insulator layer.

The individual trenches and vias are etched with predetermined depths through the corresponding openings in the resist masks. The resist masks are then removed from the insulator layer. Lastly, metal is deposited in the trenches and/or vias in order to produce the interconnects.

Resist masks are produced with conventional photolithography processes by illuminating a radiation-sensitive resist layer. By applying templates or the like, the resist layer is exposed to radiation, in particular light radiation, at predetermined positions. Either only the illuminated or only the non-illuminated regions of the resist layer are subsequently removed in a suitable developer.

In the illumination process, the beams, in particular light beams, should be projected as accurately as possible onto the surface of the resist layer according to a predetermined pattern of holes. The highest possible resolution should thereby be achieved, which is equivalent to saying that a transition that is as abrupt as possible should be obtained between illuminated and non-illuminated positions in the photoresist layer.

The illumination involves the emission, by a radiation source, of radiation which is focused by a lens onto an image plane in which the resist layer is located. In the image plane, individual substrates with the resist layers applied thereto are positioned by means of a stepper in the beam path of the beams emitted by the radiation source.

During illumination, the radiation is guided by a mask. It is possible to define a specific illumination pattern by the structure of the mask. The mask may be designed as a binary mask, for example in the form of a chromium mask. Such chromium masks have a configuration of transparent regions, which are preferably formed by a glass layer, and nontransparent layers which are formed by the chromium layers.

In order to increase the contrast of illuminated and non-illuminated regions on the resist layer, a phase mask is used instead of a chromium mask. These phase masks have predetermined patterns of optically transmissive regions in an opaque background. In order to structure the junctions of interconnects, the optically transmissive regions are designed as contact windows, the dimensions of which are matched to the geometries of the vias to be produced.

Such a phase mask may be designed, in particular, as a halftone phase mask. In such halftone phase masks, semitransmissive areas are applied extensively to a glass support at predetermined distances; the layer thicknesses of these areas are designed in such a way that the radiation passing through experiences a phase shift of 180°.

The phase mask may furthermore be designed as an alternating phase mask. Such an alternating phase mask has neighboring transparent regions, in each case separated by a chromium layer, which have phases shifted by 180° in each case. This means that the radiation passing through one transparent region is 180° out of phase relative to the radiation which is guided through the neighboring transparent region.

Finally, the phase mask may be designed as a chromeless phase mask. The chromeless phase mask consists of a configuration of optically transmissive regions, wherein neighboring regions have a phase difference of 180° in each case. At the transitions between two neighboring regions, a phase change takes place. Highly contrasting dark lines are produced along these phase-change lines in the illumination process.

It is admittedly true that the contrast during the optical projection can be increased with one of these phase masks. The disadvantage of this, however, is that the illumination parameters for illuminating the resist layer must be defined very accurately and in a narrow range.

In particular, the resist layer must be located very accurately in the focal region of the radiation. Even minor defocusing will undesirably reduce the contrast values during the illumination. Only a very narrow process window of the optical parameters, within which the illumination process gives satisfactory results, is therefore obtained for the illumination process. This leads to an illumination process which is expensive and susceptible to error.

The illumination process becomes more difficult to carry out whenever, in particular, both densely packed structures and isolated structures need to be optically projected at the same time by this process. This problem arises, in particular, in the production of junctions of interconnects, since in that case the corresponding vias may be both isolated and arranged in a densely packed way.

U.S. Pat. No. 5,446,521 discloses a halftone phase mask for a photolithography process, in which optically transmissive areas are surrounded by semitransmissive areas. In order to illuminate different resist layers, these are brought in a predetermined sequence by means of a stepper into the beam path of the radiation emitted by a radiation source. In this case, the problem is that the positioning of the resist layers, relative to the halftone phase mask located in the beam path, cannot be carried out exactly enough for the resist layers to be illuminated once only in each case. Instead, overlapping takes place at the individual positions, so that the radiation is guided repeatedly onto the resist layer through the semitransmissive layers in the edge region of the halftone phase mask, with the result that undesirably strong illumination occurs in these regions. In order to reduce this illumination, the semitransmissive layer of the halftone phase mask is designed as an opaque ring, which has a microstructure in the form of lines that are separated by transparent microlayers. This microstructure is smaller than the resolving power of the optical system, so that virtually no illumination of the photoresist layer takes place through the microstructure. The individual lines and transparent microlayers are thereby designed in such a way that the radiation preferably receives a phase difference of 180° when passing through these various microlayers, so that virtually complete extinction of the radiation takes place.

U.S. Pat. No. 5,680,588 describes an illumination system for illuminating resist layers for producing resist masks by means of a photolithography process. The illumination system comprises a radiation source that emits radiation. The radiation is guided onto the resist layer via a phase mask, a pupil system having a plurality of pixels, and a lens. The radiation source is regulated by a control unit. Using an image analyzer, the corresponding illumination patterns are analyzed and compared for various illuminations. Through evaluation of this data, the illumination is optimized by means of the control unit.

### SUMMARY OF THE INVENTION

The object of the present invention is to provide a phase mask which overcomes the above-noted deficiencies and disadvantages of the prior art devices and methods of this general kind, and which is improved in such a way that, in a photolithography process, an optimized illumination is obtained with high process reliability.

With the above and other objects in view there is provided, in accordance with the invention, a phase mask assembly for illuminating a photosensitive layer in a photolithography process for producing integrated circuits with a predetermined pattern of optically transmissive regions. The mask is formed with:

first zones with mutually adjacent optically transmissive regions spaced apart, in at least one geometrical direction, a spacing distance less than a predetermined limiting distance, and each configured as an alternating phase mask; and

second zones with mutually adjacent optically transmissive regions spaced apart a spacing distance greater than the limiting distance, and each configured as a halftone phase mask or a chromeless phase mask.

In accordance with an added feature of the invention, the phase mask has optically transmissive regions formed in an opaque background, and wherein each of the zones in which the spacing distances between adjacent optically transmissive regions are less than the limiting distance is configured as an alternating phase mask, and each of the zones in which the distances between adjacent optically transmissive regions are greater than the limiting distance is a halftone phase mask.

In accordance with an alternative embodiment of the invention, the phase mask has opaque regions in an optically transmissive background, and each zone in which the spacing distance between adjacent optically transmissive regions is less than the limiting distance is configured as an alternating phase mask, and each zone in which the spacing distances between neighboring optically transmissive regions are greater than the limiting distance is a chromeless phase mask.

In other words, the above objects are satisfied with the phase mask assembly which is configured, in zones in which the distances between neighboring optically transmissive regions in at least one geometrical direction are less than a predetermined limiting distance, in each case as an alternating phase mask. In zones in which the distances between the neighboring optically transmissive regions are greater than the limiting distance, the phase mask is in each case designed as a halftone phase mask or a chromeless phase mask. The limiting distance preferably corresponds at most to the ratio λ/NA. In this case, λ is the wavelength of the radiation used in the illumination and NA is the numerical aperture of the corresponding projection system.

In the phase mask assembly according to the invention, various zones that have different types of phase masks are hence provided. The zones are in this case matched to the distances between the individual optically transmissive regions. This exploits the fact that, in the case when the optically transmissive regions are close together, a good projection quality, and hence an abrupt transition between illuminated and non-illuminated positions in the resist layer, is obtained in a wide range of the optical projection parameters by an alternating phase mask. Such densely packed optically transmissive regions may, in particular, be formed by periodic two-dimensional structures, for example contact windows for producing junctions of interconnects. Furthermore, in zones with optically transmissive regions whose distances are above the limiting distance, a good projection quality is also obtained by using a halftone phase mask or a chromeless phase mask. It is particularly advantageous to use a halftone phase mask whenever the corresponding zone of the phase mask has optically transmissive regions in an opaque background. Conversely, a chromeless phase mask is advantageously used whenever, in the corresponding zone of the phase mask, it is necessary to project narrow dark regions in an optically transmissive background.

With the phase mask assembly according to the invention, a good projection quality is obtained, in a wide parameter range of the optical components, both for regions of densely packed and for isolated optically transmissive regions. In particular, the projection quality is also insensitive to defocusing of the radiation in a relatively large range. A large process window of the optical parameters of the illumination system, within which a virtually constantly high projection quality is achieved, is therefore obtained for the phase mask assembly according to the invention. By virtue of this optimization of the optical parameters, not only is a stable illumination process obtained, but it is also possible to project even small structures reliably on the resist layer, so that a high resolving power is achieved.

In accordance with an added feature of the invention, the optically transmissive regions are contact windows. In a preferred embodiment, in the first zones defining the alternating phase masks, the contact windows are contact chains arranged at distances smaller than the limiting distance.

In accordance with an additional feature of the invention, the second zones are halftone phase masks formed with a semitransparent phase-shifting absorber layer. Preferably, the absorber layer is configured to impart on light beams permeating the absorber layer during an illumination of the halftone phase mask during the photolithography process a phase change of 180°. The absorber layer may consist of MoSi. In a preferred embodiment, the contact windows in the second zones are holes formed in the absorber layer.

The absorber layer may be formed with blind figures (e.g., chromium surface segments) or sub-resolution structures between at least two contact windows, a distance between the contact windows corresponding to a diameter of a first-order diffraction maximum of an aerial image created when projecting the contact windows.

In accordance with again an added feature of the invention, the first zones have opaque areas formed by a chromium layer. Preferably, the chromium layers forming the opaque areas are applied to the absorber layer. Further, the chromium layers may be optically bloomed with a chromium oxide layer. Also, the absorber layer may be removed in regions forming the contact windows between the chromium layers.

In accordance with a concomitant feature of the invention, in the first zones, for generating a phase difference of 180° when light beams pass through neighboring contact windows, the glass plate is unetched in one of the contact windows and the glass plate is etched in a respectively adjacent contact window.

It is particularly advantageous to use a highly coherent laser light source, which preferably emits laser light beams in a wavelength range of from 150 nm to 380 nm, for illuminating the resist layer. A particularly wide process window is obtained with such a laser light source.

Other features which are considered as characteristic for the invention are set forth in the appended claims.

Although the invention is illustrated and described herein as embodied in a phase mask, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 is a schematic illustration of an exemplary embodiment of the phase masks according to the invention, with different zones designed as an alternating phase mask or a halftone phase mask;

FIG. 2 is a schematic illustration of a zone, designed as an alternating phase mask, in the phase mask assembly according to FIG. 1;

FIG. 3 is a similar view of a zone, designed as a halftone phase mask, in the phase mask assembly according to FIG. 1; and

FIG. 4 is a partial sectional view taken through a detail of the phase mask assembly according to FIG. 1.

### DESCRIPTION OF THE PREFERRED EMBODIMENTS

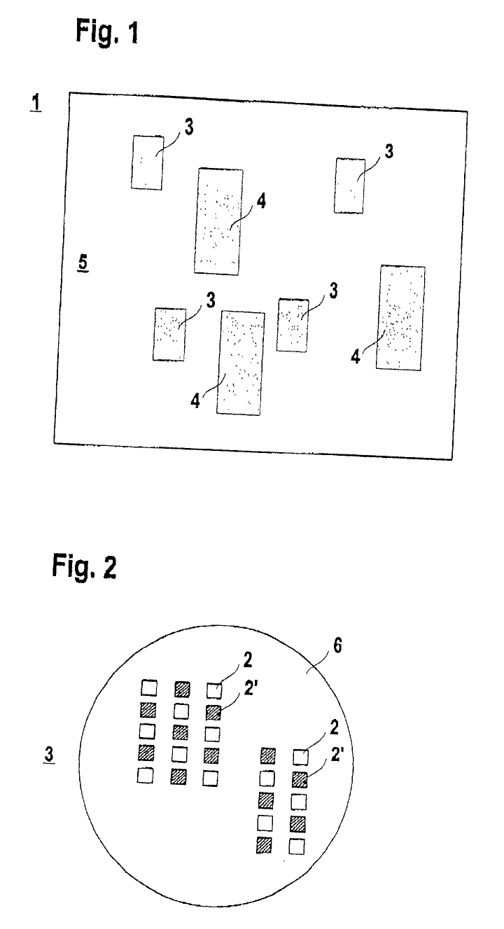

Referring now to the figures of the drawing in detail, FIGS. 1 to 4 represent an exemplary embodiment of the phase mask 1 according to the invention, which is used for illuminating photosensitive layers in a photolithography process for producing integrated circuits.

Such production processes comprise, in particular, the production of contacts for joining interconnects for wiring integrated circuits, which are arranged in a semiconductor substrate, in particular a silicon wafer.

The interconnects are incorporated in an insulator layer, which is located directly, or with the interposition of a metal layer, on the semiconductor substrate. In order to produce the interconnects, trenches and vias are etched into the insulator layer according to a predetermined pattern, and metal is subsequently deposited into them.

The pattern of the trenches and vias is defined by a resist mask, which is applied to the insulator layer. Trenches and vias are incorporated by etching through the openings in the resist mask.

The resist mask is produced by means of a photolithography process. In this case, a resist layer forming the photosensitive layer is illuminated on predetermined layers and is then developed. Depending on whether the resist layer is made of a positive or negative resist, the illuminated or non-illuminated regions of the resist layer will be removed when developing.

In order to carry out the illumination process, a radiation source that emits radiation is provided. The radiation is focused onto the resist layer by means of a lens. The layer to be illuminated in each case is moved, by means of a stepper, into the beam path of the radiation at the focal point of the lens.

The phase mask 1 according to the invention, which has optically transmissive regions in correspondence with the light pattern to be produced on the resist layer, is provided in front of the lens. These optically transmissive regions are designed as contact windows (2, 2′, 2″) in correspondence with the geometries of the vias to be produced.

In the present exemplary embodiment, a radiation source formed by a laser is provided. The laser emits radiation with highly coherent laser light beams. The wavelengths λ of the laser light beams are preferably in a range of between 150 nm and 380 nm.

By way of example, the laser used may be an argon fluoride laser which emits laser light beams at a wavelength of 193 nm. Alternatively, it is also possible to use narrow-band mercury vapor lamps which emit light beams at a wavelength of 365 nm.

The phase mask 1 illustrated in FIG. 1 is divided into different zones 3, 4, 5, the phase mask 1 being, in first zones 3 in which the contact windows 2, 2′ are arranged closer than the predetermined limiting distance in at least one geometrical direction, in each case designed as an alternating phase mask. On the other hand, the phase mask 1 is designed, in second zones 4 in which the distances between neighboring contact windows 2″ are greater than the limiting distance, in each case as a halftone phase mask. The maximum value of the limiting distance is dictated by the ratio λ/NA. In this case, λ is the wavelength of the radiation used in the photolithography process and NA is the numerical aperture of the projection system.

The first and second zones 3, 4 are in each case arranged at a distance from one another, and are separated from one another by an opaque layer on the phase mask 1, which forms the third zone 5. This opaque layer is preferably formed by a chromium layer 6.

In principle, it is also possible for the optically transmissive contact windows 2, 2′ to be arranged densely packed together in the first zones 3, which are designed as an alternating phase mask, so that the individual neighboring contact windows 2, 2′ are arranged closer to one another than the limiting distance both in the longitudinal direction and in the transverse direction of the zone 3. In the present exemplary embodiment, in the first zones 3 which are designed as an alternating phase mask, the contact windows 2, 2′ are arranged linearly one behind the other and form contact chains. FIG. 2 represents an example of such an alternating phase mask. In the longitudinal direction of a contact chain, the neighboring contact windows 2, 2′ are arranged at regular distances from one another, which are less than the limiting distance. The distances between two contact chains running beside each other are, however, greater than the limiting distance.

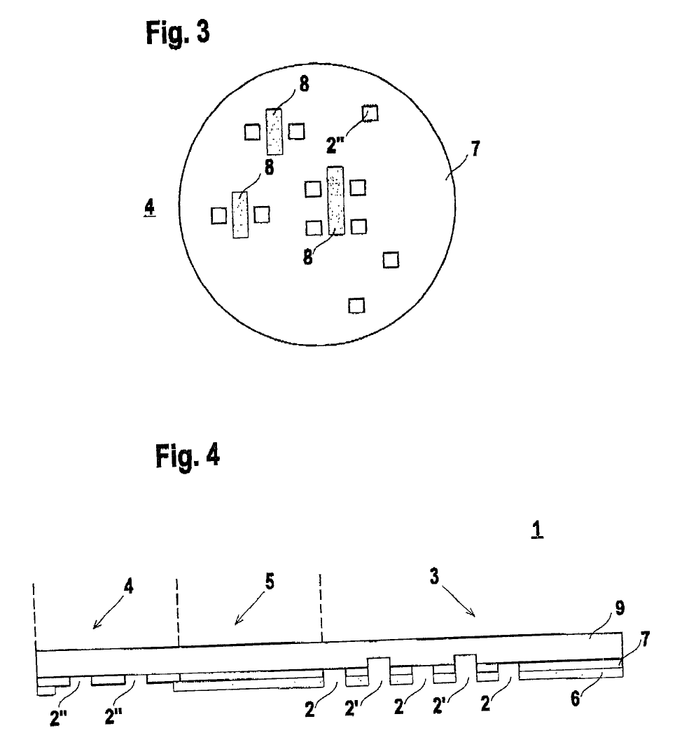

FIG. 3 represents an example of a second zone 4, designed as a halftone phase mask. The zone 4 contains contact windows 2″ between which the distances are in each case significantly greater than the limiting distance.

The zone 4, configured as a halftone phase mask, according to FIG. 3 has a semitransparent phase-shifting absorber layer 7. The isolated contact windows 2″ are designed as holes in this absorber layer 7. In the present exemplary embodiment, the contact windows 2″ once more have a square cross section. The semitransparent phase-shifting absorber layer 7 is preferably formed by a MoSi layer. The thickness of the absorber layer 7 is selected in such a way that the laser light beams incident during the illumination process receive a phase rotation of 180° when passing through the absorber layer 7.

As can further be seen in FIG. 3, local chromium surface segments 8 are applied to the absorber layer 7 at predetermined positions on the halftone phase mask. These chromium surface segments 8 form blind figures, which are used to suppress undesired parasitic structures in the illumination process. Such parasitic structures are due to interference effects of the light beams traveling through the contact windows 2″. The interfering light beams give rise to secondary interference maxima, which distort the illumination pattern in the photosensitive layer.

The opaque chromium surface segments 8 are, in each case, placed between two contact windows 2″ whenever the distances between them correspond approximately to the diameter of the first-order diffraction maximum of the aerial image of the corresponding contact windows 2″ which is produced during the projection. The area of a chromium surface segment 8 depends on the parameters of the illumination system. In addition, the size of the chromium surface segment 8 is dependent on the arrangement and the dimensions of the adjacent contact windows 2″. As can be seen in FIG. 3, the chromium surface segments 8 are designed in the form of bars, the width of a bar corresponding approximately to the width of a contact window 2, 2′, 2″. In each case, two of these contact windows 2″ lie opposite each other on either side of a chromium surface segment 8.

As an alternative to such blind figures, it is also possible to use sub-resolution structures. Such sub-resolution structures are designed as finely dimensioned transparent areas, which cannot be resolved by the projection system. These structures cause destructive interference of the transmitted light beams with the beams from the blind structures, so that no undesired parasitic structures are created by secondary intensity maxima.

Zone 3, designed as an alternating phase mask, represented in FIG. 2 consists essentially of an opaque chromium layer 6, in which the contact windows 2, 2′ are incorporated as holes. In the present example, the contact windows 2, 2′ are in each case arranged linearly one behind the other as a contact chain. As can be seen in FIG. 2, two arrays of contact windows 2, 2′ are in this case provided, three neighboring contact chains being provided in the first array and two neighboring contact chains being provided in the second array. By etching a transparent substrate located under the chromium layer 6, the contact windows 2′ are modified in such a way that, when light passes through them, a phase shift of 180° takes place in comparison with the FIG. 2. A transparent substrate is located under the chromium layer 6.

In the case of the zones 3 as well, which are configured as alternating phase masks, the cross sections of the contact windows 2, 2′ are once more of square design.

FIG. 4 shows a cross section through a detail of the phase mask 1 according to FIG. 1. In this case, FIG. 4 represents both a zone 3 designed as an alternating phase mask and a zone 4 designed as a halftone phase mask. The two zones 3, 4 are separated from one another by the chromium layer 6 in a central zone 5.

The phase mask 1 according to the invention has a glass plate 9, to which all the zones 3, 4, 5 are applied, in particular the zones 3, 4 designed as a halftone phase mask and as an alternating phase mask. Mask blanks, which are also normally used for the production of known phase masks, are preferably used as the glass plate 9.

In order to produce the phase mask 1 according to the invention, the semitransparent phase-shifting absorber layer 7 is firstly applied to the glass plate 9. A chromium layer 6 is then applied to the absorber layer 7 over its entire surface. In a particularly advantageous embodiment, the chromium layer 6 is optically bloomed with a non-illustrated chromium oxide layer.

In a first etching process, the contact windows 2, 2′, 2″ are incorporated into the phase mask 1, both in the zone 3 designed as an alternating phase mask and in the zone 4 designed as a halftone phase mask, by removing both the chromium layer 6 and the absorber layer 7 at the sites intended therefor. At the bottoms of the contact windows 2 thus formed, the surface of the glass plate 9 is then uncovered.

In a second etching process, etching is in each case continued in every other contact window 2′ of a contact chain in the zone 3 designed as an alternating phase mask, by means of which a part of the glass layer is removed in the respective contact window 2′. The glass layer is thereby removed to such an extent that the laser light beams traveling through the contact windows 2′ thus formed have a phase difference of 180° with respect to the laser light beams through the neighboring contact windows 2 of the contact chain, in which the glass layer is still fully present. FIG. 4 represents five contact windows 2, 2′ of such a contact chain, a part of the glass plate 9 being removed by etching in two contact windows 2′. The zone 3 designed as an alternating phase mask is completed by this second etching process.

The zone 4 designed as a halftone phase mask is completed by means of a third etching process, in which the entire chromium layer 6, with the exception of the chromium surface segments 8, is removed in the zone 4 designed as a halftone phase mask. In the case represented in FIG. 4, no chromium surface segments 8 are represented, so that the chromium layer 6 is fully removed in the zone 4 designed as a halftone phase mask. Between the zones 3, 4 designed as a halftone phase mask and as an alternating phase mask, the chromium layer 6 remains as an opaque separating layer and forms the third zone 5.

We claim:

1. A phase mask assembly for illuminating a photosensitive layer in a photolithography process for producing integrated circuits with a predetermined pattern, comprising:
first zones with mutually adjacent optically transmissive regions spaced apart, in at least one geometrical direction, a spacing distance less than a predetermined limiting distance, and each configured as an alternating phase mask; and
second zones with mutually adjacent optically transmissive regions spaced apart a spacing distance greater than the limiting distance, and each configured as a mask selected from the group consisting of halftone phase masks and chromeless phase masks.

2. The phase mask assembly according to claim 1, which comprises optically transmissive regions formed in an opaque background, and wherein each of the zones in which the spacing distances between adjacent optically transmissive regions are less than the limiting distance is configured as an alternating phase mask, and each of the zones in which the distances between adjacent optically transmissive regions are greater than the limiting distance is a halftone phase mask.

3. The phase mask assembly according to claim 1, which comprises opaque regions in an optically transmissive background, and each zone in which the spacing distance between adjacent optically transmissive regions is less than the limiting distance is configured as an alternating phase mask, and each zone in which the spacing distances between neighboring optically transmissive regions are greater than the limiting distance is a chromeless phase mask.

4. The phase mask assembly according to claim 1, wherein the limiting distance corresponds at most to ratio λ/NA, where λ is a wavelength of the radiation used in the photolithography process and NA is a numerical aperture of a projection system for the radiation.

5. The phase mask assembly according to claim 1, wherein said optically transmissive regions are contact windows.

6. The phase mask assembly according to claim 5, wherein, in said first zones defining said alternating phase masks, said contact windows are contact chains arranged at distances smaller than the limiting distance.

7. The phase mask assembly according to claim 1, wherein said second zones are halftone phase masks formed with a semitransparent phase-shifting absorber layer.

8. The phase mask assembly according to claim 7, wherein said absorber layer is configured to impart on light beams permeating said absorber layer during an illumination of said halftone phase mask during the photolithography process a phase change of 180°.

9. The phase mask assembly according to claim 7, wherein said absorber layer consists of MoSi.

10. The phase mask assembly according to claim 7, wherein said contact windows in said second zones are holes formed in said absorber layer.

11. The phase mask assembly according to claim 7, wherein said absorber layer is formed with blind figures or sub-resolution structures between at least two contact windows, a distance between said contact windows corresponding to a diameter of a first-order diffraction maximum of an aerial image created when projecting the contact windows.

12. The phase mask assembly according to claim 11, wherein said blind figures are formed by chromium surface segments.

13. The phase mask assembly according to claim 7, which comprises a glass plate, and said absorber layer applied to said glass plate.

14. The phase mask assembly according to claim 1, wherein said first zones have opaque areas formed by a chromium layer.

15. The phase mask assembly according to claim 14, wherein said chromium layers forming said opaque areas are applied to said absorber layer.

16. The phase mask assembly according to claim 15, wherein said chromium layers are optically bloomed with a chromium oxide layer.

17. The phase mask assembly according to claim 15, wherein said absorber layer is removed in regions forming said contact windows between said chromium layers.

18. The phase mask assembly according to claim 15, which comprises a glass plate carrying said contact windows and wherein, in said first zones, for generating a phase difference of 180° when light beams pass through neighboring contact windows, said glass plate is unetched in one of said contact windows and said glass plate is etched in a respectively adjacent contact window.

19. The phase mask assembly according to claim 1, wherein said phase masks are configured for exposure to highly coherent light beams.

20. The phase mask assembly according to claim 1, wherein said phase masks are configured for exposure to laser light beams in a wavelength range from 150 nm to 380 nm.
